(19) United States
(12) Patent Application Publication
(10) Pub. No.: US 2009/0121232 A1
(43) Pub. Date: May 14, 2009

(54) ARRAY SUBSTRATE, METHOD FOR MANUFACTURING THE SAME AND DISPLAY PANEL HAVING THE SAME

(76) Inventors: Chul HUH, Gyeonggi-do (KR); Byoung-Joo Kim, Gyeonggi-do (KR); Yui-Ku Lee, Gyeonggi-do (KR)

Correspondence Address: Haynes and Boone, LLP;IP Section, 2323 Victory Avenue, SUITE 700, Dallas, TX, 75219, US

(21) Appl. No.: 12/259,963

(22) Filed: Oct. 28, 2008

(30) Foreign Application Priority Data
Nov. 13, 2007 (KR) 10-2007-0115227

(51) Int. Cl. H01L 33/00; H01L 21/28

(52) U.S. Cl. 257/72; 438/29; 257/E33.053; 257/E21.158

(57) ABSTRACT

An array substrate, a method for manufacturing the array substrate and a display panel having the array substrate are presented. The method includes forming a thin-film transistor (TFT) on a base substrate. A passivation layer covers the TFT. A color filter layer is formed on the passivation layer. An organic protective layer is formed on the color filter layer, and has a type of photoresist that is substantially the same as that of the color filter layer. A contact hole is formed through the organic protective layer, the color filter layer and the passivation layer, partially exposing the TFT. A pixel electrode is formed on the organic protective layer to be electrically connected to a portion of the TFT. The contact hole may be formed through the organic protective layer, the color filter layer and the passivation layer by a single photolithography process, simplifying the array substrate manufacturing process.

### CROSS-REFERENCE TO RELATED APPLICATIONS

This application claims priority under 35 U.S.C. §119 to Korean Patent Application No. 2007-115227, filed on Nov. 13, 2007 in the Korean Intellectual Property Office (KIPO), the contents of which are herein incorporated by reference in their entirety.

### BACKGROUND OF THE INVENTION

1. Field of the Invention

The present invention relates to an array substrate, a method for manufacturing the array substrate and a display panel having the array substrate. More particularly, the present invention relates to an array substrate having a color filter layer, a method for manufacturing the array substrate and a display panel having the array substrate.

2. Description of the Related Art

A liquid crystal display (LCD) apparatus typically includes an LCD panel displaying an image using light, and a backlight assembly providing the light to the LCD panel.

In addition, the LCD panel includes an array substrate, opposite cover substrate and a liquid crystal layer. The array substrate includes thin-film transistors (TFTs) and pixel electrodes electrically connected to the TFTs. The cover substrate includes a common electrode which is formed on substantially the entire surface of the cover substrate that is closest to the array substrate. The liquid crystal layer is disposed between the array substrate and the cover substrate.

Generally, the cover substrate includes color filters corresponding to the pixel electrodes, but in some cases, the color filters are on the array substrate. For example, the array substrate may include the TFTs, the pixel electrodes and the color filters, and the cover substrate may include the common electrode in some embodiments.

In a method for manufacturing the array substrate having the color filters, the TFTs are formed on the base substrate, and then a passivation layer is formed to cover the TFTs. Then, a color filter layer is formed to cover the passivation layer, and the color filter layer is patterned to partially expose the passivation layer. Then, a capping layer is formed to cover the color filter layer, and the capping layer and the passivation layer are patterned to partially expose drain electrodes of the TFTs. Finally, the pixel electrodes are formed to be electrically connected to the drain electrodes, respectively, through a contact hole which is formed through the capping layer, the color filter layer and the passivation layer. In this case, the passivation layer and the capping layer are inorganic insulating layers including silicon nitride (SiNx) and silicon oxide (SiOx).

However, the conventional method for manufacturing the array substrate includes patterning processes using various masks to pattern the color filter layer, the capping layer and the passivation layer. When the various patterning processes are necessary to manufacture the array substrate, the method for manufacturing the array substrate becomes more complicated and costs for manufacturing the array substrate are increased.

### SUMMARY OF THE INVENTION

The present invention provides an array substrate capable of simplifying a manufacturing process.

The present invention also provides a method for manufacturing the array substrate.

The present invention also provides a display panel having the array substrate.

In one aspect, the array substrate according to the present invention includes a base substrate, a thin-film transistor (TFT), a passivation layer, a color filter layer, an organic protective layer and a pixel electrode. The TFT is formed on the base substrate. The passivation layer covers the TFT. The color filter layer is formed on the passivation layer.

The organic protective layer is formed on the color filter layer and has a photoresist type that is substantially the same as that of the color filter layer. The pixel electrode is formed on the organic protective layer and is electrically connected to a portion of the TFT through a contact hole. The contact hole is formed through the organic protective layer, the color filter layer and the passivation layer.

A thickness of the organic protective layer may be in a range between about 0.1 μm and about 3 μm.

The pixel electrode may make contact with a side surface of the color filter layer through the contact hole.

The color filter layer may include a color, and the organic protective layer may include an anti-diffusion additive preventing the color from being diffused into the organic protective layer.

The color filter layer and the organic protective layer may be made of a negative-type photoresist. Alternatively, the color filter layer and the organic protective layer may be made of a positive-type photoresist.

The TFT may include a gate electrode, an active pattern overlapping with the gate electrode, a source electrode partially overlapping with the active pattern, and a drain electrode spaced apart from the source electrode, partially overlapping with the active pattern, and electrically connected to the pixel electrode through the contact hole.

In another aspect, the invention is a method for manufacturing an array substrate that includes forming a TFT on a base substrate. A passivation layer is formed to cover the TFT. A color filter layer is formed on the passivation layer. An organic protective layer is formed on the color filter layer, and has a photoresist of substantially the same type as that of the color filter layer. A contact hole is formed through the organic protective layer, the color filter layer and the passivation layer, the TFT being partially exposed through the contact hole. A pixel electrode is formed on the organic protective layer to be electrically connected to a portion of the TFT through the contact hole.

The color filter layer may be formed by printing the color filter layer on the passivation layer using a printing roller. Alternatively, the color filter layer may be formed by printing the color filter layer on the passivation layer using an ink-jet nozzle.

The contact hole may be formed by forming a medium contact hole through the organic protective layer and the color filter layer so that the passivation layer is partially exposed. The passivation layer may be partially etched through the medium contact hole.

In this case, the medium contact hole may be formed by irradiating light onto the organic protective layer and the color filter layer, to selectively cure the organic protective layer and the color filter layer. Portions of the organic protective layer and the color filter layer which are uncured by the light may be removed.

The color filter layer and the organic protective layer may have negative photoresist type characteristics so that portions of the color filter layer and the organic protective layer onto which the light is irradiated may be cured. The color filter layer and the organic protective layer may include an initiator material and a monomer material that determine the characteristics of the color filter layer and the organic protective layer.

The color filter layer and the organic protective layer may have positive photoresist type characteristics so that portions of the color filter layer and the organic protective layer onto which the light is irradiated may be uncured. The color filter layer and the organic protective layer may include a photoactive compound (PAC) that determines the characteristics of the color filter layer and the organic protective layer.

In yet another aspect, the present invention is a display panel that includes an array substrate, opposite cover substrate facing the array substrate, and a liquid crystal layer disposed between the array substrate and the cover substrate.

The array substrate includes a base substrate, a TFT formed on the base substrate, a passivation layer covering the TFT, a color filter layer formed on the passivation layer, an organic protective layer formed on the color filter layer and having a photoresist of the substantially same type as that of the color filter layer, and a pixel electrode formed on the organic protective layer and electrically connected to a portion of the TFT through a contact hole, the contact hole being formed through the organic protective layer, the color filter layer and the passivation layer.

According to the present invention, an organic protective layer having a photoresist type substantially same as that of a color filter layer is formed on the color filter layer, so that the organic protective layer and the color filter layer may be patterned via a single photolithography process. Thus, a method for manufacturing an array substrate may be simplified and costs for manufacturing the array substrate may be decreased.

### BRIEF DESCRIPTION OF THE DRAWINGS

The above and other features and advantages of the present invention will become more apparent by describing in detailed example embodiments thereof with reference to the accompanying drawings, in which:

FIG. 1 is a perspective view illustrating a display panel according to an example embodiment of the present invention;

FIG. 2 is a plan view partially illustrating an array substrate of the display panel of FIG. 1;

FIG. 3 is a cross-sectional view taken along a line I-I′ of FIG. 2;

FIG. 4 is a cross-sectional view illustrating a method for forming a passivation layer covering a thin-film transistor in a method for manufacturing the array substrate of FIG. 2;

FIG. 5 is a cross-sectional view illustrating a method for forming a color filter layer in the method for manufacturing the array substrate of FIG. 2;

FIG. 6 is a cross-sectional view illustrating a method for printing the color filter layer using a printing roller of FIG. 5;

FIG. 7 is a cross-sectional view illustrating a method for forming an organic protective layer in the method for manufacturing the array substrate of FIG. 2;

FIG. 8 is a cross-sectional view illustrating a method for patterning the organic protective layer and the color filter layer having a negative photoresist type in the method for manufacturing the array substrate of FIG. 2;

FIG. 9 is a cross-sectional view illustrating a method for patterning the organic protective layer and the color filter layer having a positive photoresist type in the method for manufacturing the array substrate of FIG. 2; and

FIG. 10 is a cross-sectional view illustrating a method for partially etching the passivation layer in the method for manufacturing the array substrate of FIG. 2.

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

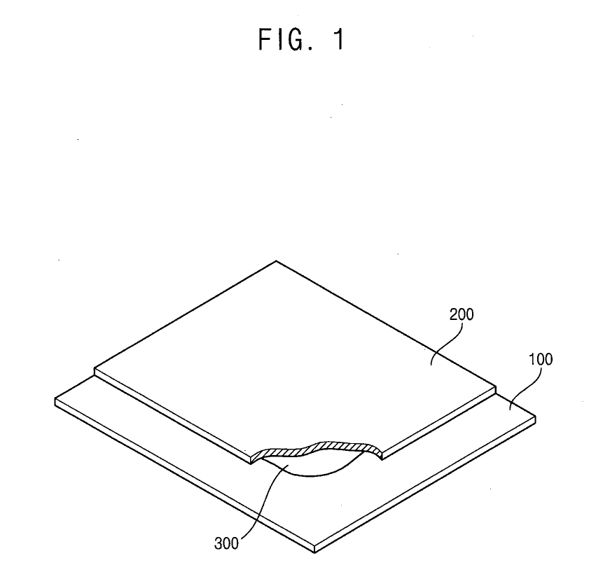

FIG. 1 is a perspective view illustrating a display panel according to an example embodiment of the present invention.

Referring to FIG. 1, the display panel according to the present example embodiment includes an array substrate 100, cover substrate 200 facing the array substrate 100, and a liquid crystal layer 300 disposed between the array substrate 100 and the cover substrate 200.

The array substrate 100 may include a plurality of signal lines, and a plurality of pixel portions electrically connected to the plurality of signal lines. The array substrate 100 will be further described in detail below.

The cover substrate 200 is disposed to face the array substrate 100. The cover substrate 200 may include a common electrode formed on substantially the entire surface of the cover substrate 200 and including a transparent conductive material.

The liquid crystal layer 300 is disposed between the array substrate 100 and the cover substrate 200. The arrangement direction of liquid crystal molecules in the liquid crystal layer 300 is changed due to an electric field generated between the pixel portions and the common electrode. When the arrangement direction of the liquid crystal molecules is changed, the light transmissivity of the liquid crystal layer 300 is changed, so that an image may be displayed.

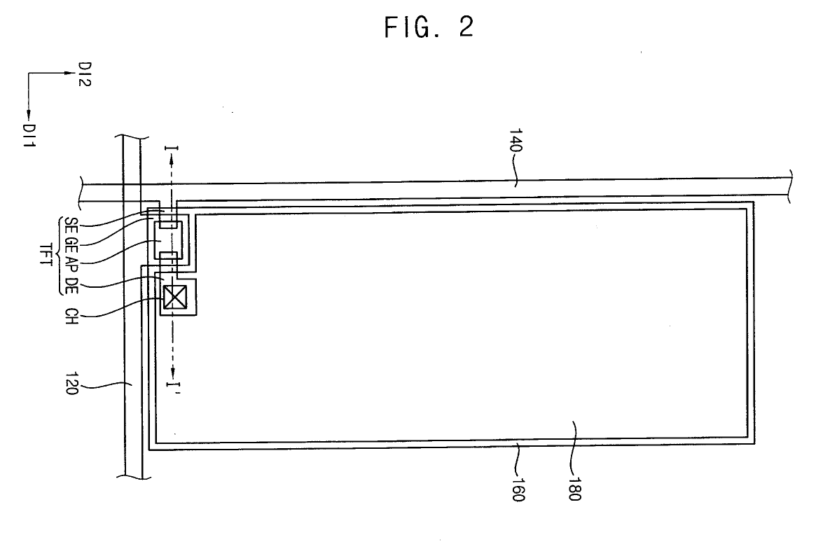

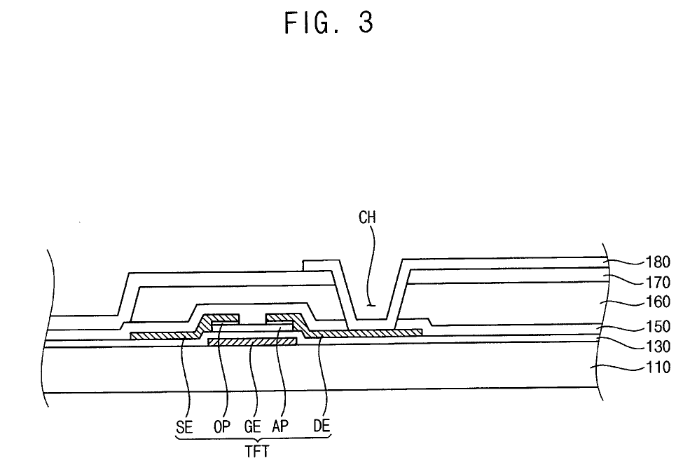

FIG. 2 is a plan view partially illustrating an array substrate of the display panel in FIG. 1. FIG. 3 is a cross-sectional view taken along a line I-I′ of FIG. 2.

Referring to FIGS. 2 and 3, the array substrate 100 according to the present example embodiment includes a base substrate 110, a gate line 120, a gate insulating layer 130, a data line 140, a thin-film transistor TFT, a passivation layer 150, a color filter layer 160, an organic protective layer 170 and a pixel electrode 180.

For example, the base substrate 110 may have a plate shape. The base substrate 110 may include a transparent material, such as glass, quartz, synthetic resin and so on.

The gate line 120 is formed on the base substrate 110, and extends along a first direction DI1. The gate line 120 is electrically connected to a gate driving circuit (not shown) generating a gate signal. The gate driving circuit may be formed on the base substrate 110.

The gate insulating layer 130 is formed on the base substrate 110, to cover the gate line 120. The gate insulating layer 130 may be an inorganic insulating layer. For example, the gate insulating layer 130 may include silicon nitride (SiNx), silicon oxide (SiOx), and so on.

The data line 140 is formed on the gate insulating layer 130, and extends along a second direction DI2 substantially perpendicular to the first direction DI1. The data line 140 may be electrically connected to a data driving circuit (not shown) generating a data signal. For example, the data driving circuit may be a driving chip disposed on the base substrate 110.

The thin-film transistor TFT may include a gate electrode GE, an active pattern AP, a source electrode SE, a drain electrode DE and an ohmic contact pattern OP.

The gate electrode GE is electrically connected to the gate line 120. For example, the gate electrode GE may be a portion of the gate line 120. Alternatively, the gate electrode GE may be an extension from the gate line 120 along the second direction DI2.

The active pattern AP is formed on the gate insulating layer 130 to overlap the gate electrode GE.

The source electrode SE is formed on the gate insulating layer 130, to be electrically connected to the data line 140. For example, the source electrode SE may be a portion of the data line 140. Alternatively, the source electrode SE may be an extension from the data line 140 along the first direction DI1. The source electrode SE is formed on the active pattern AP to partially overlap the active pattern AP.

The drain electrode DE is spaced apart from the source electrode SE, and is formed on the gate insulating layer 130. The drain electrode DE is formed on the active pattern AP to partially overlap the active pattern AP.

The ohmic contact pattern OP is formed between the source electrode SE and the active pattern AP, and between the drain electrode DE and the active pattern AP. The ohmic contact pattern OP may decrease contact resistance between the source electrode SE and the active pattern AP, and contact resistance between the drain electrode DE and the active pattern AP. For example, the active pattern AP may include amorphous silicon, and the ohmic contact pattern OP may include amorphous silicon doped with ions at a high concentration.

The passivation layer 150 is formed on the gate insulating layer 130 to cover the thin-film transistor TFT and the data line 140. Thus, the passivation layer 150 may protect the thin-film transistor TFT and the data line 140.

The passivation layer 150 may be an inorganic insulating layer similar to the gate insulating layer 130. For example, the passivation layer 150 may include silicon nitride (SiNx), silicon oxide (SiOx) and so on.

The color filter layer 160 is formed on the passivation layer 150. The color filter layer 160 includes a plurality of color filter patterns respectively formed in a plurality of unit pixels. The color filter layer 160 includes colors. For example, the color filter layer 160 may include red color filter patterns having red colors, green color filter patterns having green colors and blue color filter patterns having blue colors.

The color filter layer 160 may include a negative photoresist type material or a positive photoresist type material.

The organic protective layer 170 is formed on the passivation layer 150 to cover the color filter layer 160. The organic protective layer 170 has a type of photoresist that is substantially the same as that of the color filter layer 160. For example, when the color filter layer 160 has a negative-type photoresist, the organic protective layer 170 also has a negative-type photoresist, and when the color filter layer 160 has a positive-type photoresist, the organic protective layer 170 also has a positive-type photoresist.

A contact hole CH is formed through the organic protective layer 170, the color filter layer 160 and the passivation layer 150, to partially expose the drain electrode DE of the thin-film transistor TFT.

The pixel electrode 180 includes the transparent conductive material, and is formed in each of the unit pixels. For example, the pixel electrode 180 may include indium tin oxide (ITO), indium zinc oxide (IZO), and so on.

The pixel electrode 180 is formed on the organic protective layer 170, and electrically makes contact with the drain electrode DE through the contact hole CH. In addition, the pixel electrode 180 may make contact with a side surface of the organic protective layer 170 and a side surface of the color filter layer 160 through the contact hole CH.

Accordingly, the organic protective layer 170 covers and protects the color filter layer 160, so that the colors included in the color filter layer 160 may be prevented from diffusing into to the pixel electrode.

In this case, the organic protective layer 170 is thinner than the color filter layer. For example, the thickness of the organic protective layer 170 may be in a range between about 0.1 μm and about 3 μm, and preferably between about 1 μm and about 1.5 μm. When the thickness of the organic protective layer 170 is less than about 0.1 μm, the colors in the color filter layer 160 may easily diffuse into the pixel electrode 180 via the organic protective layer 170. When the thickness of the organic protective layer 170 is greater than about 3 μm, a problem may occur with the interface between the pixel electrode 180 and the drain electrode DE.

In addition, the organic protective layer 170 may include an anti-diffusion additive preventing the colors in the color filter layer 160 from diffusing into the organic protective layer 170. The anti-diffusion additive may be a polymer. The polymer may be electrically combined with the pixel electrode in order not to contaminate the pixel electrode, even if the polymer makes contact with the pixel electrode. In addition, light may pass through the polymer.

In the present example embodiment, the pixel electrode 180 may make contact with the side surface of the color filter layer 160 through the contact hole CH. Thus, the colors in the color filter layer 160 may diffuse into the pixel electrode via the side surface of the color filter layer 160, contaminating the pixel electrode 180.

Thus, few colors exist or a density of the colors tends to be low in a region adjacent to the side surface of the color filter layer 160 making contact with the pixel electrode 180.

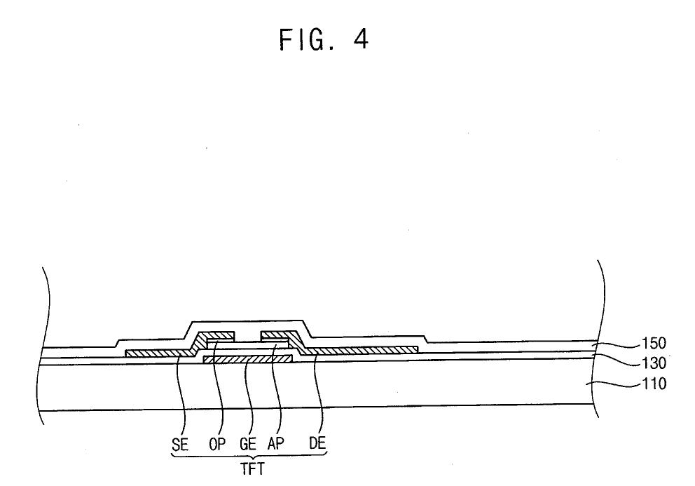

FIG. 4 is a cross-sectional view illustrating a method for forming a passivation layer covering a thin-film transistor TFT in a method for manufacturing the array substrate in FIG. 2.

Referring to FIGS. 2 and 4, the gate line 120, the gate insulating layer 130, the data line 140 and the thin-film transistor TFT are formed on the base substrate 110.

For example, the gate line 120 and the gate electrode GE of the thin-film transistor TFT may be formed on the base substrate 110, and the gate insulating layer 130 are formed to cover the gate line 120 and the gate electrode GE. Then, the active pattern AP and the ohmic pattern OP are formed on the gate insulating layer 130, and the date line 140, the source electrode SE and the drain electrode DE are formed.

Then, the passivation layer 150 is formed on the base substrate 110 to cover the data line 140 and the thin-film transistor TFT.

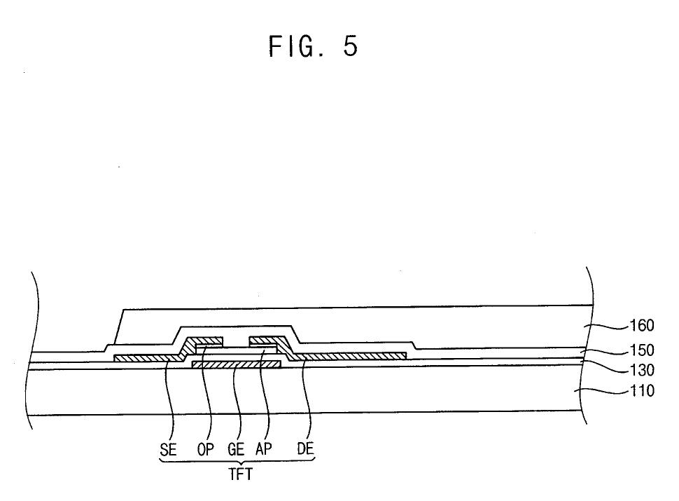

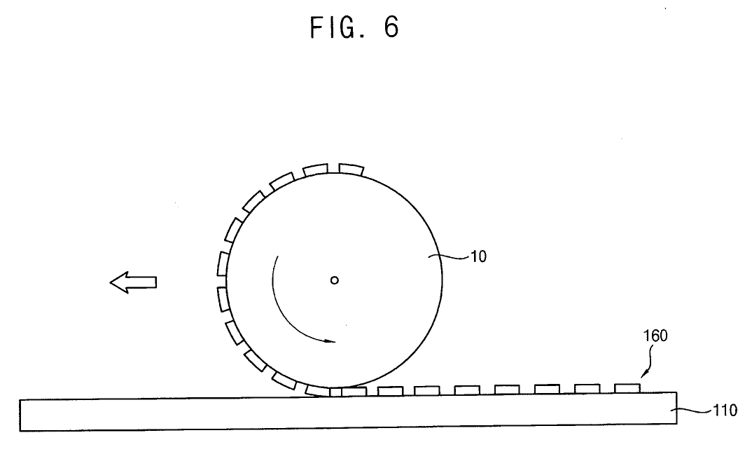

FIG. 5 is a cross-sectional view illustrating a method for forming a color filter layer in the method for manufacturing the array substrate in FIG. 2. FIG. 6 is a cross-sectional view illustrating a method for printing the color filter layer using a printing roller in FIG. 5.

Referring to FIGS. 2, 5 and 6, after the passivation layer 150 is formed, the color filter layer 160 is formed on the passivation layer 150. The color filter layer 160 may be formed on the passivation layer 150 using one of various well-known printing methods.

For example, as illustrated in FIG. 6, the color filter layer 160 may be printed by a printing roller 10. In this case, when the printing roller 10 is rolled on the base substrate 110, the color filter patterns disposed on an outer surface of the printing roller 10 may be printed on the passivation layer 150.

Alternatively, the color filter layer 160 may be printed on the passivation layer 150 by an ink-jet nozzle (not shown). In this case, the ink-jet nozzle sprays inks onto the passivation layer 150, forming the color filter layer 160.

The color filter layer 160 may be the negative photoresist type or the positive photoresist type.

For example, when the color filter layer 160 is made of a negative-type photoresist, the color filter layer 160 may include a solvent material, a binder material, an initiator material, a monomer material, a color material and various additives.

In this case, the solvent material is evaporated as time goes on, and the binder material forms a main structure of the color filter layer 160. The initiator material reacts with the monomer material when the light is irradiated, and the monomer material reacts with the initiator material to form a chain between the binder materials. When the monomer material forms the chain between the binder materials, the binder materials may be cured.

Alternatively, when the color filter layer 160 is made of a positive-type photoresist type, the color filter layer 160 may include the solvent material, the binder material, a photoactive compound (PAC), the color material and the various additives.

In this case, the PAC is disposed between the binder materials to cure the binder materials. However, the PAC may uncure the binder materials when the light is irradiated to the PAC.

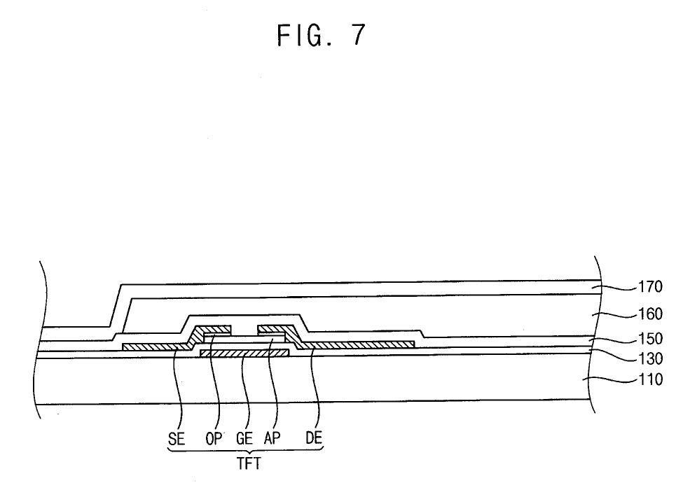

FIG. 7 is a cross-sectional view illustrating a method for forming an organic protective layer in the method for manufacturing the array substrate in FIG. 2.

Referring to FIG. 7, after the color filter layer 160 is formed, the organic protective layer 170 may be formed on the passivation layer 150 to cover the color filter layer 160.

The organic protective layer 170 has a photoresist of substantially the same type as that of the color filter layer 160.

For example, when the organic protective layer 170 is of the negative photoresist type, the organic protective layer 170 may include the solvent material, the binder material, the initiator material, the monomer material and various additives.

Alternatively, when the organic protective layer 170 is of the positive photoresist type, the organic protective layer 170 may include the solvent material, the binder material, the PAC and the various additives.

Accordingly, the organic protective layer 170 may include substantially the same materials as the color filter layer 160, except for the color material.

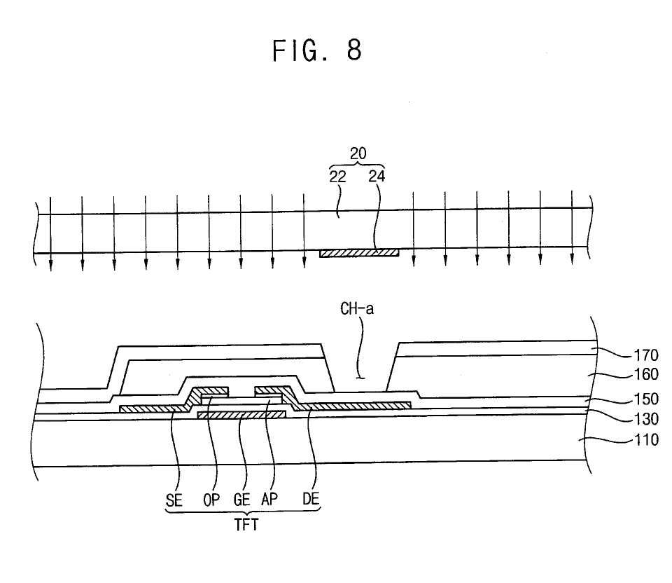

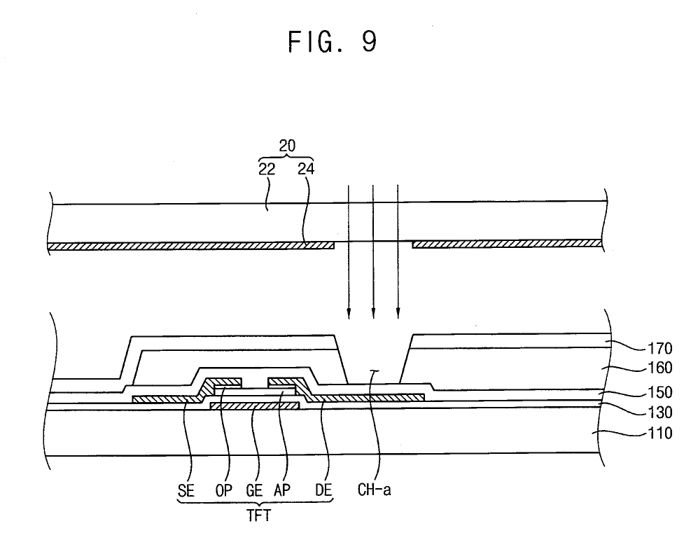

FIG. 8 is a cross-sectional view illustrating a method for patterning the organic protective layer and the color filter layer having a negative photoresist type in the method for manufacturing the array substrate of FIG. 2. FIG. 9 is a cross-sectional view illustrating a method for patterning the organic protective layer and the color filter layer having a positive photoresist type in the method for manufacturing the array substrate in FIG. 2.

Referring to FIGS. 8 and 9, after the organic protective layer 170 is formed, the organic protective layer 170 and the color filter layer 160 are partially etched, so that a medium contact hole CH-a is formed through the organic protective layer 170 and the color filter layer 160. In this case, the medium contact hole CH-a is formed above the drain electrode DE of the thin-film transistor TFT.

When the organic protective layer 170 and the color filter layer 160 are of the negative photoresist type, portions of the organic protective layer 170 and the color filter layer 160 onto which the light is irradiated are cured, and portions of the organic protective layer 170 and the color filter layer 160 onto which the light is not irradiated are uncured, as illustrated in FIG. 8. In this case, the portions of the organic protective layer 170 and the color filter layer 160 which are uncured are removed, and the portions of the organic protective layer 170 and the color filter layer 160 which are cured remain.

Alternatively, when the organic protective layer 170 and the color filter layer 160 are of the positive photoresist type, the portions of the organic protective layer 170 and the color filter layer 160 onto which the light is irradiated may be uncured, and the portions of the organic protective layer 170 and the color filter layer 160 onto which the light is not irradiated may be cured.

A mask 20 used for patterning the organic protective layer 170 and the color filter layer 160 may include a transparent plate 22, and a mask pattern 24 formed on the transparent plate 22 to block the light. In this case, when the organic protective layer 170 and the color filter layer 160 are of the negative photoresist type, the mask pattern 24 is disposed to correspond to the medium contact hole CH-a. When the organic protective layer 170 and the color filter layer 160 are of the positive photoresist type, the mask pattern 24 is disposed at a region through which the medium contact hole CH-a is not formed.

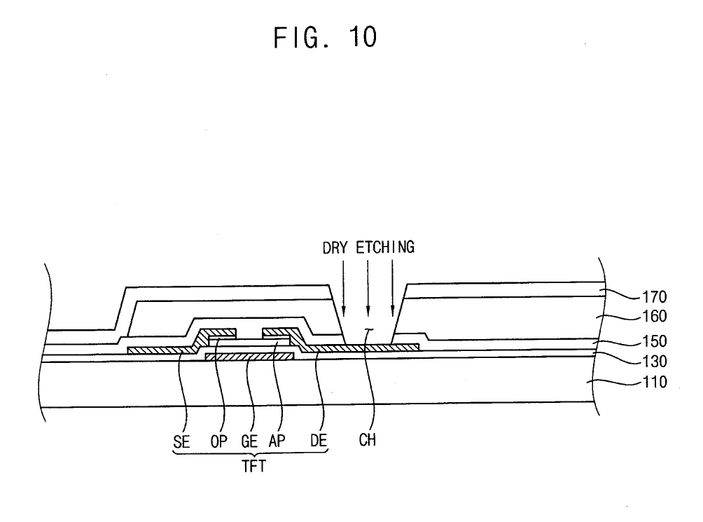

FIG. 10 is a cross-sectional view illustrating a method for partially etching the passivation layer in the method for manufacturing the array substrate in FIG. 2.

Referring to FIG. 10, the medium contact hole CH-a is formed through the organic protective layer 170 and the color filter layer 160, and then the passivation layer 150 is partially etched using the medium contact hole CH-a. Thus, the contact hole CH exposing a portion of the drain electrode DE may be formed. In this case, the passivation layer 150 is partially etched via a dry etching method using plasma.

Referring to FIG. 3 again, the pixel electrode 180 is formed on the organic protective layer 170. In this case, the pixel electrode 180 is electrically connected to the portion of the drain electrode DE through the contact hole CH that extends through the organic protective layer 170, the color filter layer 160 and the passivation layer 150.

According to the present invention, the organic protective layer 170 and the color filter layer 160 may be patterned via the same single photolithography process to form the medium contact hole, and then the passivation layer 150 may be partially dry-etched using the medium contact hole.

Thus, the invention allows patterning of the organic protective layer 170 and the color filter layer 160 and various lithography processes to pattern the passivation layer 150 to be omitted, simplifying the method for manufacturing the array substrate 100 and reducing the cost of manufacturing the array substrate 100.

Having described the example embodiments of the present invention and its advantage, it is noted that various changes, substitutions and alterations can be made herein without departing from the spirit and scope of the invention as defined by appended claims.

What is claimed is:

1. An array substrate comprising:
a base substrate;
a thin-film transistor (TFT) formed on the base substrate;
a passivation layer covering the TFT;
a color filter layer formed on the passivation layer;
an organic protective layer formed on the color filter layer, the organic protective layer having a photoresist type that is substantially the same as that of the color filter layer; and
a pixel electrode formed on the organic protective layer and electrically connected to a portion of the TFT through a contact hole, the contact hole being formed through the organic protective layer, the color filter layer and the passivation layer.

2. The array substrate of claim 1, wherein a thickness of the organic protective layer is in a range between about 0.1 μm and about 3 μm.

3. The array substrate of claim 1, wherein the pixel electrode makes contact with a side surface of the color filter layer through the contact hole.

4. The array substrate of claim 1, wherein the color filter layer comprises a color, and the organic protective layer comprises an anti-diffusion additive preventing the color from being diffused into the organic protective layer.

5. The array substrate of claim 1, wherein the color filter layer and the organic protective layer are made of a negative-type photoresist.

6. The array substrate of claim 1, wherein the color filter layer and the organic protective layer are made of a positive-type photoresist.

7. The array substrate of claim 1, wherein the TFT comprises:
a gate electrode;
an active pattern overlapping with the gate electrode;
a source electrode partially overlapping with the active pattern; and
a drain electrode spaced apart from the source electrode, partially overlapping with the active pattern, and electrically connected to the pixel electrode through the contact hole.

8. A method for manufacturing an array substrate, the method comprising:
forming a TFT on a base substrate;
forming a passivation layer to cover the TFT;
forming a color filter layer on the passivation layer;
forming an organic protective layer on the color filter layer, the organic protective layer having a photoresist of substantially the same type as that of the color filter layer;
forming a contact hole through the organic protective layer, the color filter layer and the passivation layer, the TFT being partially exposed through the contact hole; and
forming a pixel electrode on the organic protective layer to be electrically connected to a portion of the TFT through the contact hole.

9. The method of claim 8, wherein the color filter layer is formed by printing the color filter layer on the passivation layer using a printing roller.

10. The method of claim 8, wherein the color filter layer is formed by printing the color filter layer on the passivation layer using an ink-jet nozzle.

11. The method of claim 8, wherein the contact hole is formed by:
forming a medium contact hole through the organic protective layer and the color filter layer so that the passivation layer is partially exposed; and
partially etching the passivation layer through the medium contact hole.

12. The method of claim 11, wherein the medium contact hole is formed by:
irradiating light onto the organic protective layer and the color filter layer to selectively cure the organic protective layer and the color filter layer; and
removing portions of the organic protective layer and the color filter layer which are uncured.

13. The method of claim 12, wherein the color filter layer and the organic protective layer have negative photoresist type characteristics so that portions of the color filter layer and the organic protective layer onto which the light is irradiated are cured.

14. The method of claim 13, wherein the color filter layer and the organic protective layer include an initiator material and a monomer material that determine the characteristics of the color filter layer and the organic protective layer.

15. The method of claim 12, wherein the color filter layer and the organic protective layer have positive photoresist type characteristics so that portions of the color filter layer and the organic protective layer onto which the light is irradiated are uncured.

16. The method of claim 15, wherein the color filter layer and the organic protective layer include a photoactive compound (PAC) that determines the characteristics of the color filter layer and the organic protective layer.

17. The method of claim 11, wherein the contact hole is formed by selectively removing the passivation layer via a dry etching method using plasma.

18. A display panel comprising:
an array substrate including:
a base substrate;
a TFT formed on the base substrate;
a passivation layer covering the TFT;
a color filter layer formed on the passivation layer;
an organic protective layer formed on the color filter layer and having a photoresist type substantially same as that of the color filter layer; and
a pixel electrode formed on the organic protective layer and electrically connected to a portion of the TFT through a contact hole, the contact hole being formed through the organic protective layer, the color filter layer and the passivation layer;
a cover substrate facing the array substrate; and
a liquid crystal layer disposed between the array substrate and the cover substrate.
